(19) United States
(12) Patent Application Publication
(10) Pub. No.: US 2008/0284482 A1
(43) Pub. Date: Nov. 20, 2008

(54) SEMICONDUCTOR CIRCUIT

(75) Inventor: Katsumi Ishikawa, Hitachinaka (JP)

Correspondence Address: ANTONELLI, TERRY, STOUT & KRAUS, LLP, 1300 NORTH SEVENTEENTH STREET, SUITE 1800, ARLINGTON, VA, 22209-3873, US

(73) Assignee: Hitachi, Ltd.

(21) Appl. No.: 12/122,145

(22) Filed: May 16, 2008

(30) Foreign Application Priority Data
May 16, 2007 (JP) 2007-130803

(51) Int. Cl. H03K 3/00; H01L 29/12

(52) U.S. Cl. 327/291; 257/76; 257/E29.068

(57) ABSTRACT

A semiconductor circuit for an inverter device, comprising a pulse generator for generating a pulse signal upon receiving the input signal for controlling the high-voltage switching device of the inverter device, a driver circuit for driving the high-voltage switching device, and a signal transfer circuit for transferring the pulse signal generated by the pulse generator to the driver circuit, wherein a wide band-gap semiconductor device is used in the signal transfer circuit

### BACKGROUND OF THE INVENTION

This invention relates to a semiconductor circuit for driving the switching devices of, for example, an inverter.

An inverter usually comprises, for example, a switching device constituting a low-voltage arm (hereafter referred to as lower side) and a switching device constituting a high-voltage arm (hereafter referred to as upper side). In such an inverter configuration, those switching devices are connected in series with each other between the terminals of a main power source.

The switching devices of the upper side is driven by a power source isolated from the main power source by means of a transformer and therefore having its reference potential floating with respect to the reference voltage of the main power source. In the case where the upper-side switching device is driven by the floating power source, when it is necessary to transfer the signal for driving the lower-side switching device to the driver circuit for driving the upper-side switching device, a level shift-up circuit must be used to step up its voltage. Alternatively, there are some other cases where when the signal for driving the upper-side switching device is required to be transferred to the driver circuit for driving the lower-side switching device, a level shift-down circuit is used to step down its voltage.

Recently, such driver circuits for driving switching devices and such a level shift-up and level shift-down circuit as mentioned above have been put to practical use in the form of integrated circuits such as, for example, gate driver ICs and widely known in the public domain. For example, Japanese Patent No. 3,092,862 will be one of the related techniques.

FIG. 10 shows a semiconductor circuit according to the conventional art, which comprises a lower-side drive circuit 21 and an upper-side drive circuit 22. The lower-side drive circuit 21 consists mainly of a pulse generator 31, silicon (Si)-nMOSFETs 13, 14 having high blocking voltage, and a driver circuit 32.

The upper-side drive circuit 22 consists mainly of a reset-set (RS) flip-flop 37, and a driver circuit 38. In addition, a level shift circuit includes passive parts and a power source. The concrete configuration and the detailed operation of the level shift circuit are well known and therefore only the operations of active parts will be mainly described here.

Upon receiving the input signal for the upper side, the pulse generator 31 of the lower-side drive circuit 21 delivers a pulse signal to the gate of the high blocking-voltage Si-nMOSFET 14 and, after a certain delay, also delivers a pulse signal to the gate of the high blocking-voltage Si-nMOSFET 13.

The high blocking-voltage Si-nMOSFETs 13, 14 have their drain/source channels rendered conductive when they receive at their gates the pulse signals generated by the pulse generator 31. When the pulse generator 31 delivers a pulse signal (set pulse) to the gate of the high blocking-voltage Si-nMOSFET 14, the drain/source channel of the high blocking-voltage Si-nMOSFET 14 is turned conductive as shown in FIG. 11. Accordingly, the signal at the set (S) terminal of the RS flip-flop 37 takes “L” (low) level. As a result, the potential at the Q output terminal of the RS flip-flop 37 becomes “H” (high) level. This H level potential causes the driver circuit 38 to deliver an H level signal to the gate of the upper-side switching device (IGBT in this case) 52 so that the potential at the emitter of the switching device 52 is increased up to an H level.

Thereafter, the pulse generator 31 delivers a pulse signal (reset pulse) to the gate of the high blocking-voltage Si-nMOSFET 13 so that the drain/source channel of the high blocking-voltage Si-nMOSFET 13 is turned conductive. Accordingly, the signal at the reset (R) terminal of the RS flip-flop 37 takes “L” (low) level. As a result, the potential at the Q output terminal of the RS flip-flop 37 becomes “L” (low) level. This L level potential causes the driver circuit 38 to deliver an L level signal to the gate of the upper-side switching device (IGBT in this case) 52 so that the potential at the emitter of the switching devicet 52 is decreased down to an L level.

In this exemplary circuit, the heat generation by the high blocking-voltage Si-nMOSFETs 13, 14 is suppressed by driving them with pulse signals.

Namely, while the high blocking-voltage Si-nMOSFET 13 is being driven by the pulse generator 31, a current determined by the power source voltage and the sum of the resistance R1 and the source/drain channel resistance of the high blocking-voltage Si-nMOSFET 13 flows through the source/drain channel of the high blocking-voltage Si-nMOSFET 13, whereas while the high blocking-voltage Si-nMOSFET 14 is being driven by the pulse generator 31, a current determined by the power source voltage and the sum of the resistance R2 and the source/drain channel resistance of the high blocking-voltage Si-nMOSFET 14 flows through the source/drain channel of the high blocking-voltage Si-nMOSFET 14. Since the high blocking-voltage Si-nMOSFETs 13, 14 generate heat while they are conductive, the width of the gating pulse should preferably be shorter.

On the other hand, when the switching device 52 is turned on by the drive signal from the driver circuit 38 corresponding to the set signal at the S terminal of the RS flip-flop 37, a sudden change occurs in the emitter potential of the switching device (IGBT in this case) 52. If the transient period associated with the rate of the change, i.e. dv/dt, prolongs, noise occurs in the set signal or the reset signal to the RS flip-flop 37 and therefore the switching device 52 may be undesirably turned on or off. In order to prevent such undesirable turn-on or turn-off of the switching device, the above mentioned Japanese Patent No. 3,092,862 discloses a system which uses a pulse filter so as to improve the capability of removing harmful effect due to the rate of the change, i.e. dv/dt.

### SUMMARY TO THE INVENTION

In circuits using conventional pulse filters, however, it is necessary to prolong the time constant of each pulse filter if the value of dv/dt is small. The increase in the time constant of the pulse filter must be necessarily accompanied by the increase in the pulse width of the set pulse or the reset pulse. This fails to meet the above mentioned requirement that the pulse width must be preferably shorter.

This invention, which has been made to resolve such a problem, aims to provide a semiconductor circuit which can reconcile such apparently incompatible needs arising in the control of switching devices with pulse signals.

According to this invention, there is provided a semiconductor circuit for driving an inverter device with a load connected at the potential at the intermediate point between the high-voltage switching device and the low-voltage switching device, comprising a pulse generator for generating pulse signals in response to the input signals supplied thereto at the time instants which correspond to the turn-on and turn-off of the high-voltage switching device in the inverter device, a driver circuit for driving the high-voltage switching device, and a signal transfer circuit for transferring the pulse signals generated by the pulse generator to the driver circuit, wherein a wide band-gap semiconductor device is used in the signal transfer circuit to transfer pulse signals.

The wide band-gap semiconductor device used in the signal transfer circuit may be selected from among a SiC device, a GaN device and a device made of diamond.

Further, the wide band-gap semiconductor device used in the signal transfer circuit may be selected from among a MOSFETs, a junction FETs and an IGBTs.

Furthermore, this semiconductor circuit may comprise a metal substrate, silicon chips provided on the metal substrate and having the driver circuits formed thereon, and a wide band-gap semiconductor device mounted on the metal substrate and connected with the driver circuits through wire bonding.

In this case, the silicon chips and the wide band-gap semiconductor device may be attached to the metal substrate by soldering with high melting-point solder.

Further, a plurality of wide band-gap semiconductor devices may be mounted on the metal substrate, with the bonding wires connecting the wide band-gap semiconductor devices with the driver circuits having substantially the same lengths.

In addition, the wide band-gap semiconductor device may be formed by disposing the driver circuits on the silicon substrate and selectively forming a GaN layer on one portion of the surface of the silicon substrate.

Other objects, features and advantages of the invention will become apparent from the following description of the embodiments of the invention taken in conjunction with the accompanying drawings.

### BRIEF DESCRIPTION OF THE DRAWINGS

FIG. 1 shows in block diagram a semiconductor circuit as a half bridge IGBT module according to an embodiment of this invention;

FIG. 2 shows in block diagram a semiconductor circuit according to another embodiment of this invention;

FIG. 3 shows waveforms of the voltages applied to the gates of the switching devices (MOSFETs), waveforms of the set and reset signals for RS flip-flop, and waveforms of the voltages applied to the power switching devices (IGBTs), for illustrating the operation of the semiconductor circuit shown in FIG. 2;

FIG. 4 shows in perspective view a semiconductor circuit according to this invention implemented in the form of an integrated circuit;

FIG. 5 shows in block diagram a semiconductor circuit in the form of a half bridge IGBT module according to yet another embodiment of this invention;

FIG. 6 shows in block diagram a semiconductor circuit according to still another embodiment of this invention;

FIG. 7 shows in perspective view a semiconductor circuit having the signal transfer circuit 27 as shown in FIG. 6, implemented in the form of an integrated circuit, according to this invention;

FIG. 8 illustrates in a cross-sectional view a method for forming such an integrated semiconductor circuit as shown in FIG. 7 on, for example, a silicon substrate;

FIG. 9 shows a semiconductor circuit as a still further embodiment of this invention, which corresponds to the embodiment shown in FIG. 1;

FIG. 10 schematically shows a conventional example of a semiconductor circuit for driving switching devices of an inverter; and

FIG. 11 shows various waveforms appearing at important circuit points in the semiconductor circuit shown in FIG. 10.

### DETAILED DESCRIPTION OF THE INVENTION

Embodiments of this invention will now be described with reference to the attached drawings. A semiconductor circuit as an embodiment of this invention serves to drive an inverter device which has a load connected at the potential at the intermediate point between the upper-side switching device and the lower-side switching device of the inverter, and uses wide band-gap semiconductor elements in its circuit for transferring signals to drive the inverter device.

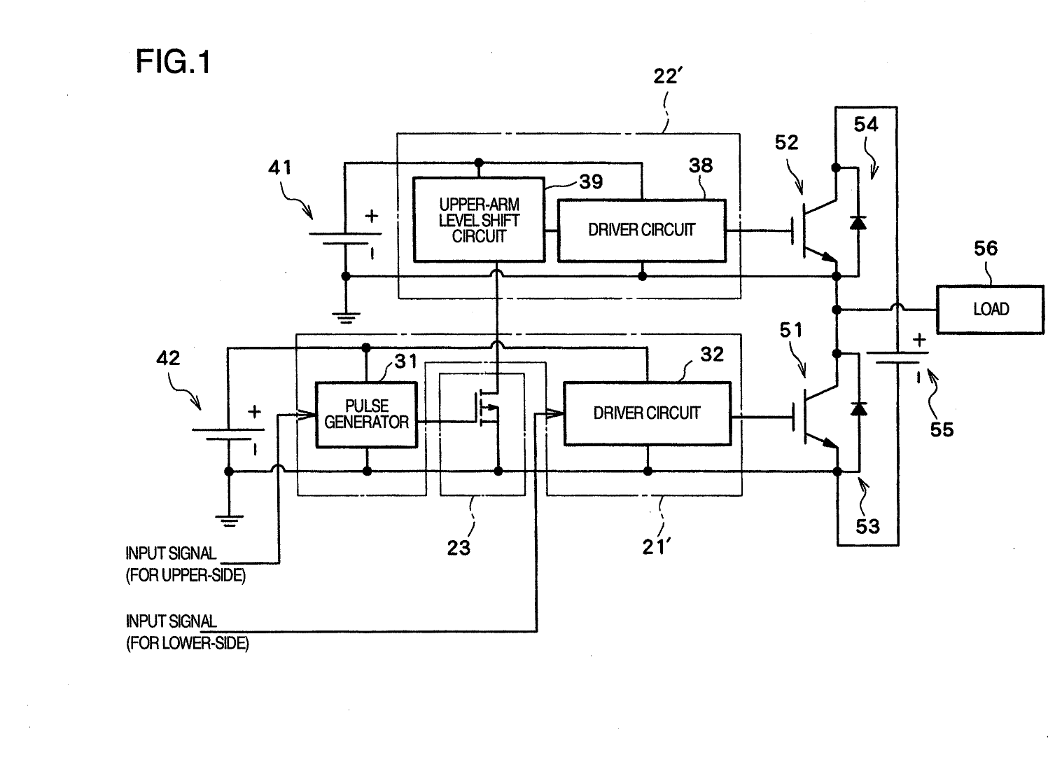

FIG. 1 shows in block diagram a semiconductor circuit as a half bridge IGBT module according to an embodiment of this invention. The circuit comprises a lower-side drive circuit 21′, an upper-arm drive circuit 22′, a signal transfer circuit 23 including a SiC(silicon carbide)-MOSFET, and power sources 41, 42. The outputs of the lower-side and upper-arm drive circuits 21′, 22′ are connected with the gate terminals of voltage-controlled switching devices (IGBTs in this case) 51, 52.

The IGBTs 51, 52, which are the objects of control, are connected in series with each other, and the series-connected pair is connected between the positive and negative terminals of a power source 55. A load 56 is connected at the potential at the intermediate point between the IGBTs 51, 52. A free-wheel diode is connected between the emitter and collector of each of the IGBTs 51, 52 to protect them.

The lower-side drive circuit 21′ includes a pulse generator 31 and a driver circuit 32 whereas the upper-side drive circuit 22′ includes an upper-side level shift circuit 39 and a driver circuit 38.

The pulse generator 31 delivers a pulse signal upon receiving an input signal for the upper side. The pulse signal is applied to the gate terminal of the SiC-MOSFET that serves as the signal transfer circuit 23. Accordingly, the SiC-MOSFET is turned on, sending a signal to the level shift-up circuit 39. As a result, the level shift-up circuit 39 so controls the driver circuit 38 as to drive the switching device 52 into the conductive state.

When an input signal for the lower-side arrives, the driver circuit 32 is actuated to drive the lower-side switching device 51 into the conductive state.

One feature of this embodiment is that the SiC-MOSFET as an example of wide band-gap semiconductor device is used in the signal transfer circuit 23. The use of the SiC-MOSFET enables the on resistance of the signal transfer circuit 23 to be reduced to about one tenth of the on resistance of a switching device other than Si power device, and therefore enables the associated loss as generated heat to be reduced. Further, the use of the SiC-MOSFET in the signal transfer circuit 23 reduces the heat generation in the device as a whole, and also provides high heat conductivity which enables the signal transfer circuit 23 to operate at higher temperatures.

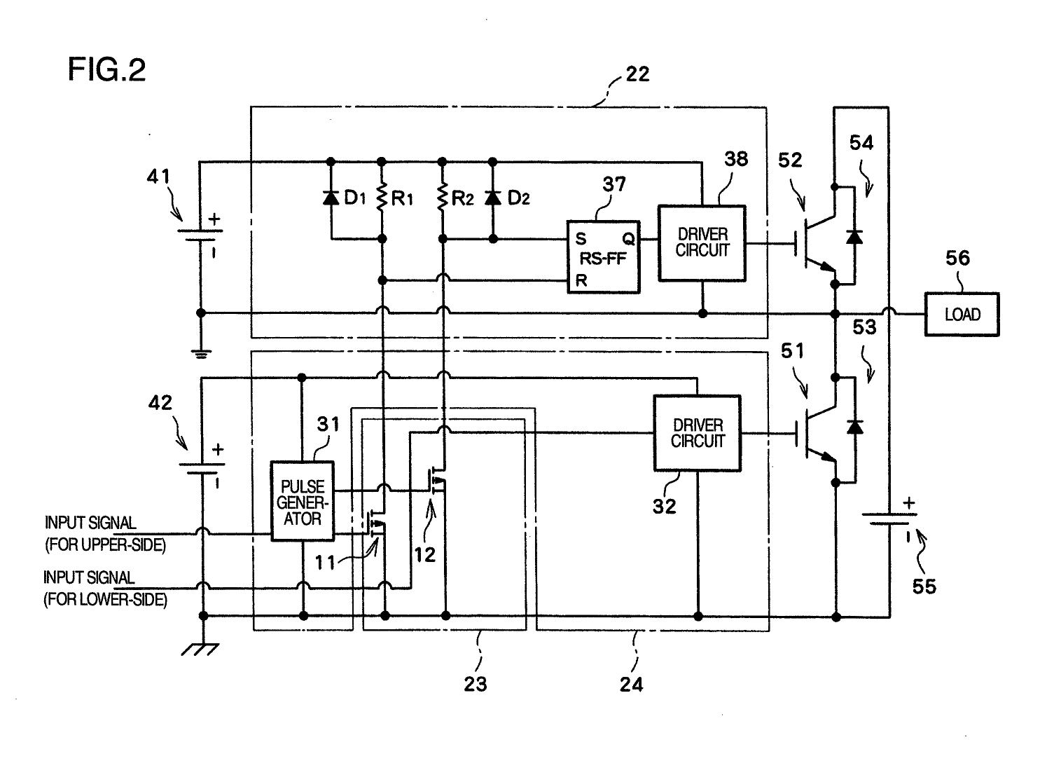

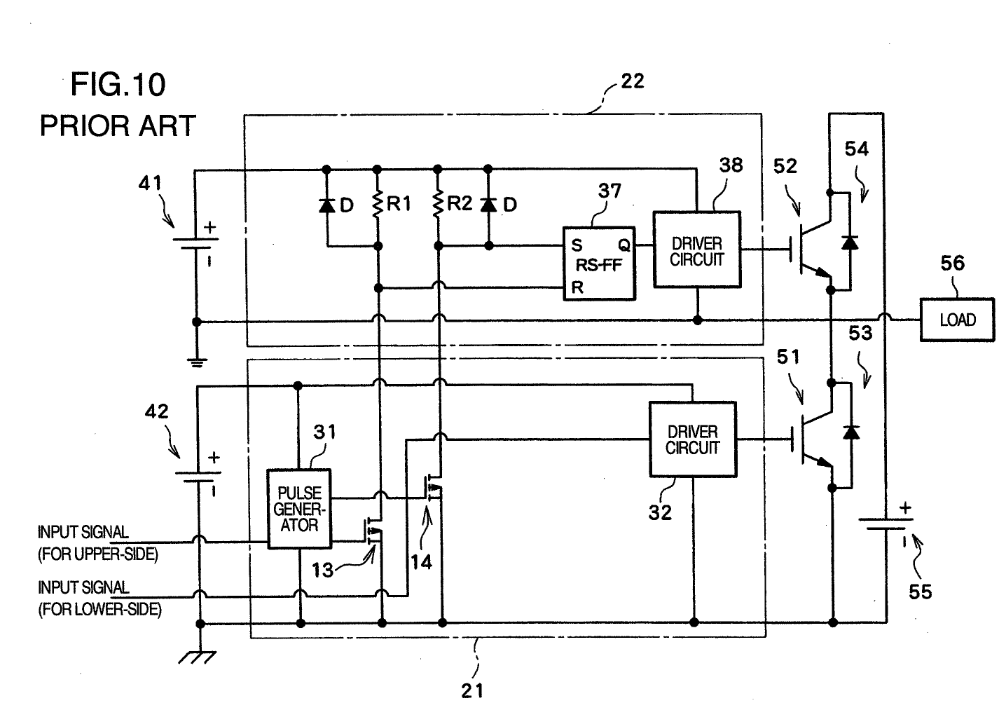

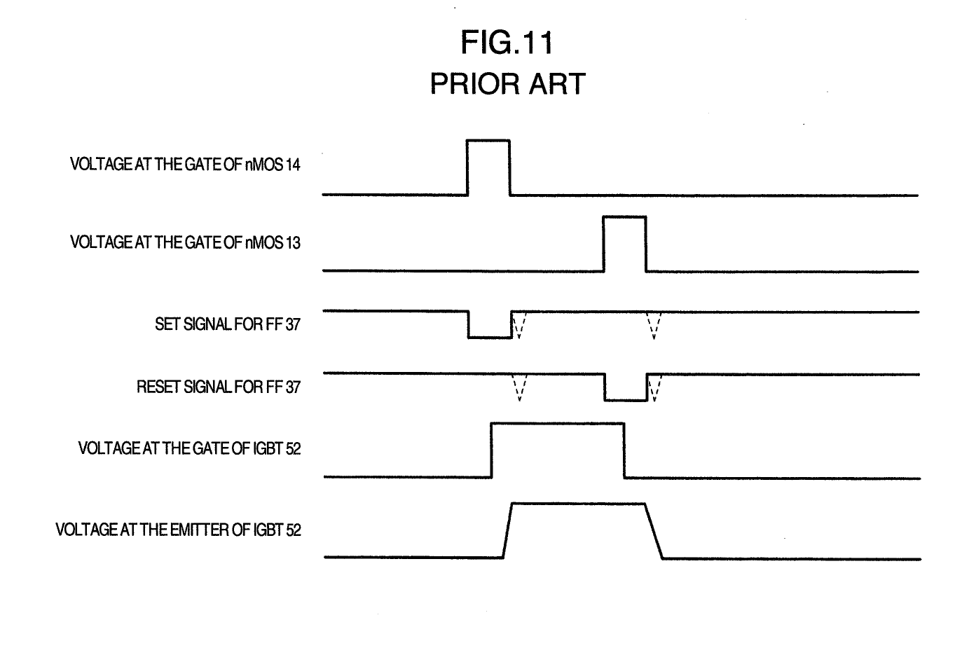

FIG. 2 shows in block diagram a semiconductor circuit as another embodiment of this invention. This circuit corresponds to the drive circuit for driving the power semiconductor devices as shown in FIG. 10. The semiconductor circuit of this embodiment comprises a lower-side drive circuit 24, an upper-side drive circuit 22 and a signal transfer circuit 23. The lower-side drive circuit 24 includes a pulse generator 31 and a driver circuit 32 whereas the upper-side drive circuit 22 includes a rest-set (RS) flip-flop 37 and a driver circuit 38. The semiconductor circuit further comprises level shift circuits, each consisting of a resistor R and a zener diode D connected in parallel with each other, and power circuits. In FIG. 2, there are components which operate in the same manner as those shown in FIG. 10 and therefore those components are designated by like numerals and the detailed descriptions thereof will be omitted.

The outputs of the lower-side and upper-side drive circuits 24, 22 are applied to the gate terminals of the corresponding voltage controlled switching devices (IGBT in this case) 51, 52.

The IGBTs 51, 52, are connected in series with each other, and the series-connected pair is connected between the positive and negative terminals of a power source 55. A load 56 is connected at the potential at the intermediate point between the IGBTs 51, 52. A free-wheel diode is connected between the emitter and collector of each of the IGBTs 51, 52 to protect them.

The signal transfer circuit 23 includes SiC-nMOSFETs 11, 12 which are examples of wide band-gap semiconductor device.

Upon receiving the input signal for the upper-side, the pulse generator 31 of the lower-side drive circuit 24 delivers a pulse signal to the gate of the SiC-nMOSFET 12 in the signal transfer circuit 23 and also delivers, after a certain delay, a pulse signal to the gate of the SiC-nMOSFET 11.

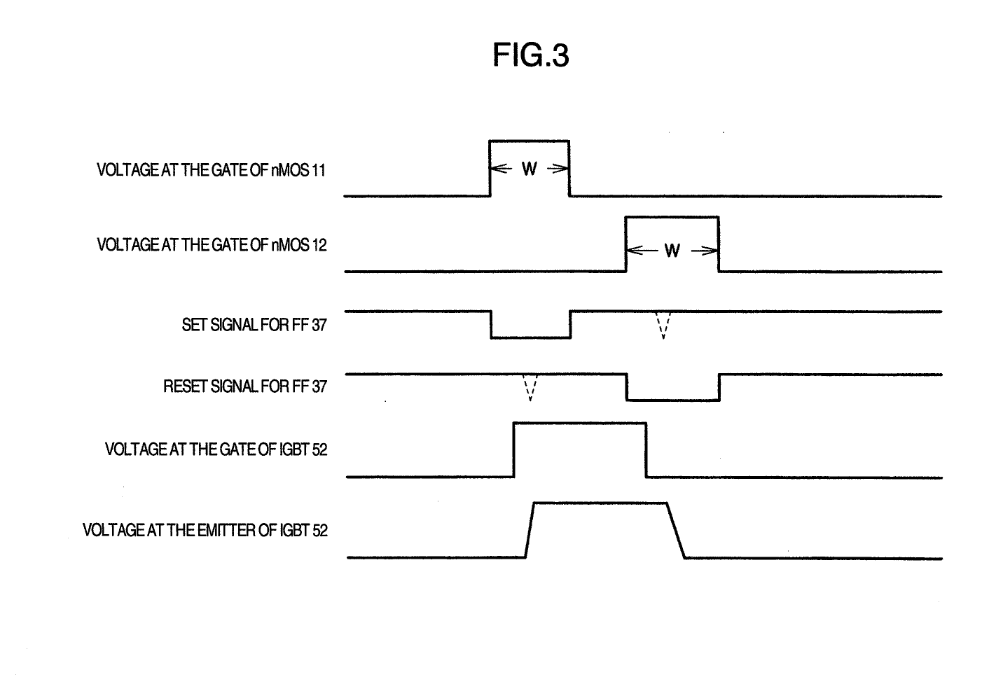

When the SiC-MOSFETs 11, 12 of the signal transfer circuit 23 receive at their gates the pulse signals from the pulse generator 31, their drain/source channels turn conductive. When the pulse generator 31 issues a pulse signal (i.e. set pulse) to the gate of the SiC-nMOSFET 12, the drain/source channel of the high blocking-voltage SiC-nMOSFET 12 becomes conductive as shown in FIG. 3. Accordingly, the set (S) terminal of the RS flip-flop 37 is rendered to the “L” level, and therefore the output terminal Q of the RS flip-flop 37 is rendered to the “H” level. Upon receiving the “H” level signal from the RS flip-flop 37, the driver circuit 38 issues an “H” level signal to the gate of the switching device (IGBT in this case) 52 of the upper-side drive circuit 22. As a result, the potential at the emitter of the switching device 52 increases up to an “H” level. All these situations are shown in FIG. 3.

After a certain delay, the pulse generator 31 issues a pulse signal (i.e. reset pulse) to the gate of the SiC-nMOSFET 11 so that the drain/source channel of the high blocking-voltage SiC-nMOSFET 11 becomes conductive. Accordingly, the reset (R) terminal of the RS flip-flop 37 is rendered to the “L” level, and therefore the output terminal Q of the RS flip-flop 37 is rendered to the “L” level. Upon receiving the “L” level signal from the RS flip-flop 37, the driver circuit 38 issues an “L” level signal to the gate of the switching device (IGBT in this case) 52 of the upper-side. As a result, the potential at the emitter of the switching device 52 decreases down to an “L” level. All these situations are also shown in FIG. 3.

According to this embodiment, as compared with the case where ordinary Si devices are used as switching devices in the signal transfer circuit 23, the turn-on resistance of the wide band-gap semiconductor device (i.e. SiC device) is one tenth of that of the Si device, so that the loss due to low loss. Consequently, even though the pulse width of the set or reset signal supplied to the RS flip-flop 37 is increased, the loss in the signal transfer circuit 23 is still small. Further, the SiC device, made of wide band-gap semiconductor, has high heat conductivity which enables the operation at high temperatures and therefore seldom performs an erroneous operation at high temperatures. Namely, as shown in FIG. 3, the widths of the driving pulse signals can be made long enough to prevent the IGBTs as switching elements from being erroneously turned on or off.

In the semiconductor circuit as described above, the SiC-nMOSFET 11, 12 are used, but junction FETs (JFETs) made of SiC or IGBTs may be equally used instead. If SiC-JFETs are used in place of SiC-nMOSFETs, the loss will further be reduced, which leads to the improvement in reliability.

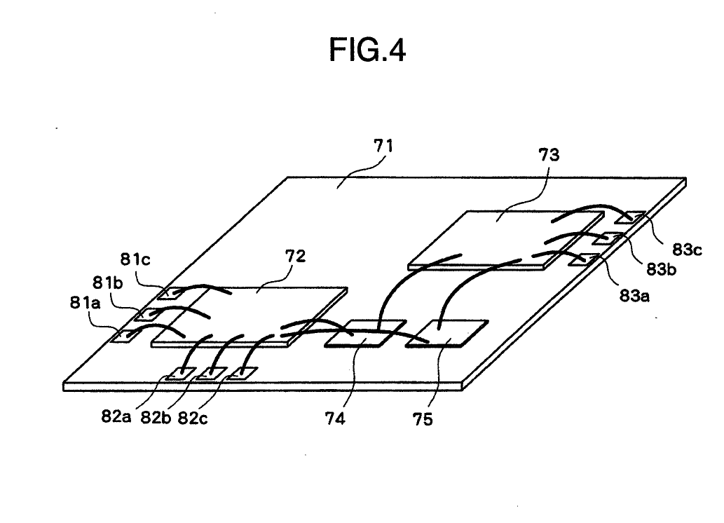

The semiconductor circuit according to this embodiment may be implemented in the form of an integrated circuit. In such a case, as shown in FIG. 4a silicon (Si) chip 72 including the lower-side drive circuit 24 and a silicon (Si) chip 73 including the upper-side drive circuit 21 are formed on a substrate 71 made of metal such as alloy or copper. In addition, chips 74, 75 respectively including the SiC-nMOSFETs 11, 12 of the signal transfer circuit 23 are also formed on the substrate 71. Moreover, bonding pads 81a, 81b, 81c, 82a, 82b, 82c, 83a, 83b and 83c are disposed on the substrate 71. The terminals of each chip are connected through bonding wire with these bonding pads. Furthermore, the SiC-nMOSFETs 11, 12 of the signal transfer circuit 23 are connected through bonding wire with the silicon chips 72, 73. In this case, the chips 72, 73 and the SiC-nMOSFETs 11, 12 may be attached to the metal substrate 71 by soldering with high melting-point solder.

A geometrical configuration may also be employed such that the length of the bonding wire connecting the SiC-nMOSFET 74 with the silicon chip 72 is the same as the length of the bonding wire connecting the SiC-nMOSFET 75 with the silicon chip 72 and that the length of the bonding wire connecting the SiC-nMOSFET 74 with the silicon chip 72 is the same as the length of the bonding wire connecting the SiC-nMOSFET 75 with the silicon chip 73.

In the semiconductor circuit as an IC version according to this embodiment, the chips 74, 75 including the SiC-nMOSFETs 11, 12 are separately provided apart from the Si chips 72, 73. This layout wherein the SiC devices that tend to generate much heat are disposed apart from the Si chips, enables the whole semiconductor circuit to operate in a wider range of temperatures, as compared with the circuit including only Si chips.

In the semiconductor circuit as described above, the chips 74, 75 including the SiC-nMOSFET 11, 12 are used, but chips including junction FETs (JFETs) made of SiC or IGBTs may be equally used instead. If SiC-JFETs are used in place of SiC-nMOSFETs, the loss will further be reduced, which leads to the improvement in reliability.

There is a case where when an abnormal condition is detected in the upper-side circuit, a pulse signal is transferred from the upper-side circuit to the lower-side circuit. In such a case, the pulse width of the pulse signal transferred from the upper-side circuit to the lower-side circuit is to be set short, e.g. not more than several microseconds, in order to prevent excessive current from flowing through the level shift circuit of the lower-side circuit. Hence, it is considered that wide band-gap semiconductor devices should be used even in the signal transfer circuit which transmits a pulse signal from the upper-side circuit to the lower-side circuit.

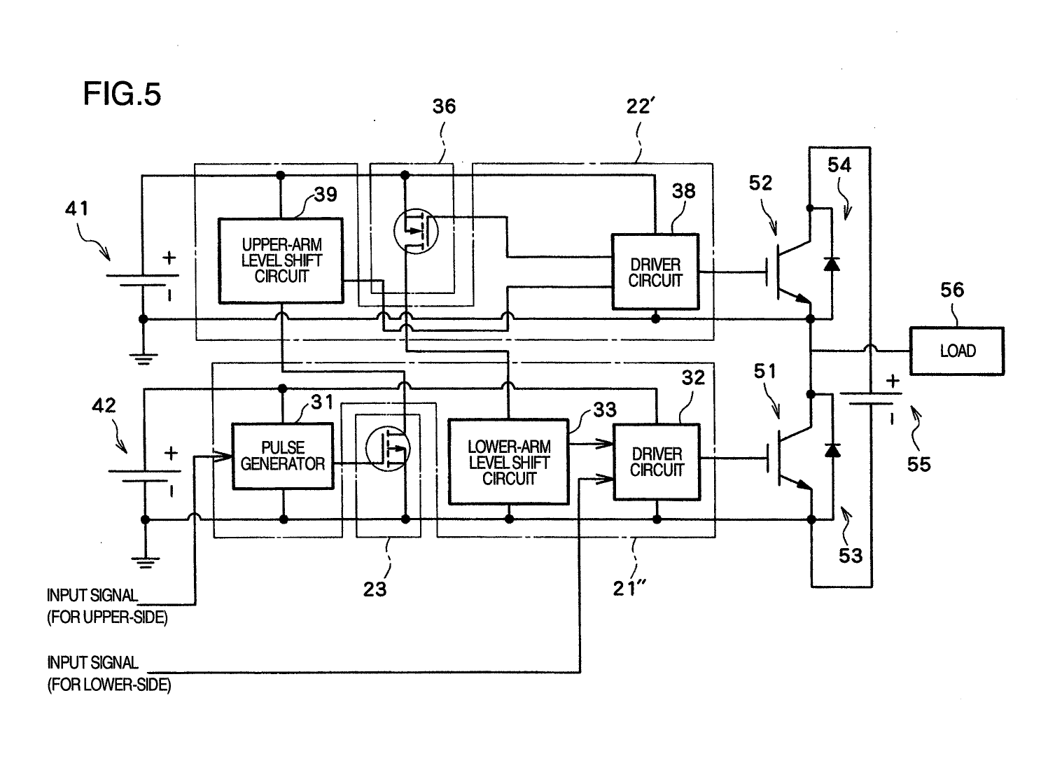

FIG. 5 shows in block diagram a semiconductor circuit in the form of a half bridge IGBT module according to yet another embodiment of this invention. As shown in FIG. 5, the semiconductor circuit comprises a lower-side drive circuit 21″, an upper-side drive circuit 22′, signal transfer circuits 23, 36 respectively including SiC-MOSFETs, and power sources 41, 42. The outputs of the drive circuits 21″, 22′ are supplied to the gate terminals of the corresponding voltage-driven switching devices (IGBT in this case) 51, 52.

The IGBTs 51, 52, which are the objects of control, are connected in series with each other, and the series-connected pair is connected between the positive and negative terminals of a power source 55. A load 56 is connected at the potential at the intermediate point between the IGBTs 51, 52. Free-wheel diodes 53, 54 are connected between the emitter and collector of the IGBT 51, and between the emitter and collector of the IGBT 52, respectively, to protect them.

The lower-side drive circuit 21″ comprises a pulse generator 31, a driver circuit 32 and a lower-side level shift circuit 33 whereas the upper-side drive circuit 21′ comprises an upper-side level shift circuit 39 and a driver circuit 38. In FIG. 5, there are components which operate in the same manner as those shown in FIG. 1 and therefore those components are designated by like numerals and the detailed descriptions thereof will be omitted.

In this semiconductor circuit, a SiC-nMOSFET as an example of wide band-gap semiconductor device is used in the signal transfer circuit 23 for transferring a signal from the lower-side drive circuit 21″ to the upper-side drive circuit 22′ whereas a SiC-pMOSFET as another example of wide band-gap semiconductor device is used in the signal transfer circuit 36 for transferring a signal from the upper-side drive circuit 22′ to the lower-side drive circuit 21″. In this way, since the signal transfer circuit 36 for transferring a signal from the upper-side drive circuit 22′ to the lower-side drive circuit 21″ employs a wide band-gap semiconductor device (SiC device in this case) that has higher heat conductivity than the Si device and thus can operate at higher temperatures, a higher stability in signal transfer in the event of an abnormality can be achieved.

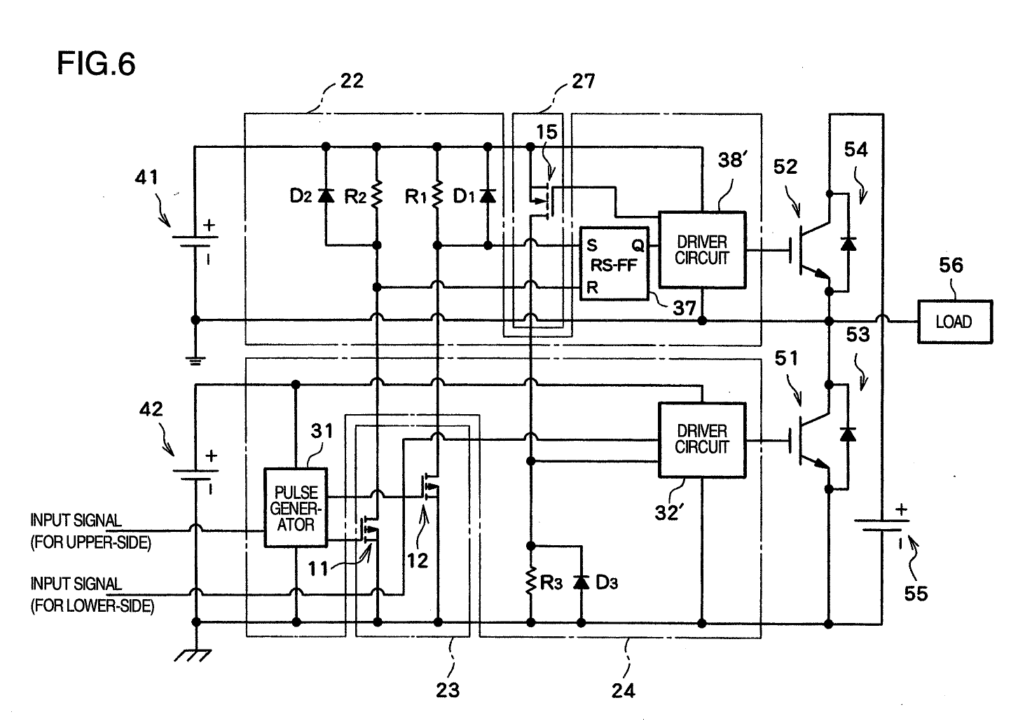

FIG. 6 shows in block diagram a semiconductor circuit according to still another embodiment of this invention, wherein a signal transfer circuit for transferring a signal from the upper-side drive circuit to the lower-side drive circuit is provided. A notable feature of the semiconductor circuit shown in FIG. 6, that is, the difference from the semiconductor circuit shown in FIG. 2 is the provision of the circuit for transferring a signal from the upper-side drive circuit to the lower-side drive circuit. The semiconductor circuit comprises a lower-side drive circuit 24, an upper-side drive circuit 22, and signal transfer circuits 23, 27. The lower-side drive circuit 24 includes a pulse generator 31 and a driver circuit 32′ whereas the upper-side drive circuit 22 includes a reset-set (RS) flip-fop 37 and a driver circuit 38′. The semiconductor circuit further comprises level shift circuits, each consisting of a resistor R and a zener diode D connected in parallel with each other, and power circuits. In FIG. 6, there are components which operate in the same manner as those shown in FIG. 2 and therefore those components are designated by like numerals and the detailed descriptions thereof will be omitted.

The outputs of the lower-side and upper-side drive circuits 24, 22 are applied respectively to the gate terminals of the corresponding voltage-driven switching devices (IGBT in this case) 51, 52.

The IGBTs 51, 52, which are the objects of control, are connected in series with each other, and the series-connected pair is connected between the positive and negative terminals of a power source 55. A load 56 is connected at the potential at the intermediate point between the IGBTs 51, 52. Free-wheel diodes 53, 54 are connected between the emitter and collector of the IGBT 51, and between the emitter and collector of the IGBT 52, respectively, to protect them.

The signal transfer circuit 23 includes SiC-nMOSFETs 11, 12 which are examples of wide band-gap semiconductor devices.

In this embodiment, when the driver circuit 38′ of the upper-side drive circuit 22 detects an abnormality, it issues a pulse signal indicating the abnormality to the signal transfer circuit 27. The signal transfer circuit 27, including a SiC-pMOSFET 15, receives the pulse signal issued from the driver circuit 38′ at the gate terminal of the SiC-pMOSFET 15. Then, the SiC-pMOSFET 15 of the signal transfer circuit 27 is turned on to render its source/drain channel conductive. Consequently, the signal transfer circuit 27 supplies to the driver circuit 32′ a signal whose voltage is determined by the level shift circuit (consisting of a resistor R3 and a zener diode D3) of the lower-side drive circuit 24. As a result, the driver circuit 32′ stops driving the IGBT 51.

Thus, according to this embodiment, by using the SiC-pMOSFET 15, which is an example of wide band-gap semiconductor device, in the signal transfer circuit 27 that transfers the signal from the upper-side drive circuit 22 to the lower-side drive circuit 24, the turn-on resistance and the associated heat generation can be reduced as compared with the case where a Si device is used in the signal transfer circuit 27. Further, since the SiC device has higher heat conductivity than the Si device, that is, since the former can operate at higher temperatures than the latter, the SiC device can achieve the stable transfer of the abnormality indicating signal.

In the signal transfer circuit 27 described above, the SiC-pMOSFET 15 are used, but a junction FET (JFET) made of SiC or a p-gate IGBT may be equally used instead. If the SiC-JFET is used in place of the SiC-pMOSFET, the loss will further be reduced, which leads to the improvement in reliability.

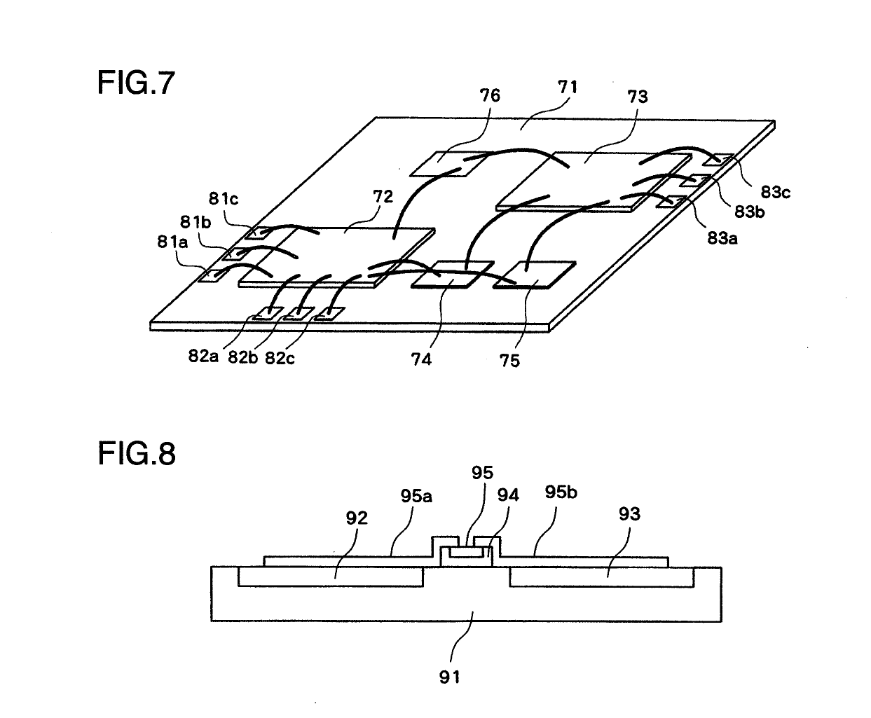

FIG. 7 shows in perspective view a semiconductor circuit having the signal transfer circuit 27 as shown in FIG. 6, implemented in the form of an integrated circuit, according to this invention. In FIG. 7, there are components which operate in the same manner as those shown in FIG. 4 and therefore those components are designated by like numerals and the detailed descriptions thereof will be omitted. In this embodiment shown in FIG. 7, in addition to the bonding pads 81a, 81b, 81c, 82a, 82b, 82c, 83a, 83b and 83c; the silicon (Si) chips 72, 73; and the SiC-nMOSFETs 11, 12 of the signal transfer circuit 23, all mounted on the substrate 71 as shown in FIG. 4, a chip 76 including the SiC-pMOSFET 15 is mounted on the substrate 71, and the chip 76 is connected through wire bonding with the Si chips 72, 73 respectively carrying thereon the upper-side and lower-side drive circuits 22, 24. Since the SiC chip 76 is formed on the substrate 71, separate from the chips 72, 73, the operating range of temperatures can be expanded upward. In this case, the Si chips 72, 73; the SiC-nMOSFETs 11, 12, which are wide band-gap semiconductor devices, of the signal transfer circuit 23; and the SiC-pMOSFET 15 may be attached to the metal substrate 71 by soldering with high melting-point solder.

A geometrical configuration may also be employed such that the length of the bonding wire connecting the SiC-nMOSFET 74 with the silicon chip 72 is the same as the length of the bonding wire connecting the SiC-nMOSFET 75 with the silicon chip 72, that the length of the bonding wire connecting the SiC-nMOSFET 74 with the silicon chip 73 is the same as the length of the bonding wire connecting the SiC-nMOSFET 75 with the silicon chip 73, and that the length of the bonding wire connecting the SiC-pMOSFET 76 with the silicon chip 72 and the silicon chip 73 is the same as the length of the bonding wire connecting the SiC-nMOSFET 75 with the silicon chip 72 and the silicon chip 73.

FIG. 8 illustrates a method for forming such an integrated semiconductor circuit as shown in FIG. 7 on, for example, a silicon substrate. FIG. 8 is a cross-sectional view of such an integrated semiconductor circuit.

First, in the formation of the integrated semiconductor circuit as an embodiment shown FIG. 7, a lower-side drive circuit 92 and an upper-side drive circuit 93 are formed in one surface of a silicon substrate 91 through the diffusion process that is used in the fabrication of ordinary Si semiconductor devices. Then, an epitaxial layer 94 of gallium nitride GaN is grown on the one surface of the silicon substrate 91. Further, a layer of GaN is formed in the surface of the epitaxial GaN layer 94 through diffusion process. Thus, an FET (95, 95a, 95b) serving as a signal transfer circuit is fabricated. This FET using GaN is a MOSFET or a junction FET.

In the semiconductor circuit according to this embodiment using the SiC device as the signal transfer circuit, the on resistance of the signal transfer circuit can be reduced to about one tenth of the on resistance of a Si device, and therefore the associated loss can be reduced. This effect of reducing heat generation in the semiconductor device can eliminate the necessity of driving the signal transfer circuit with a pulse signal.

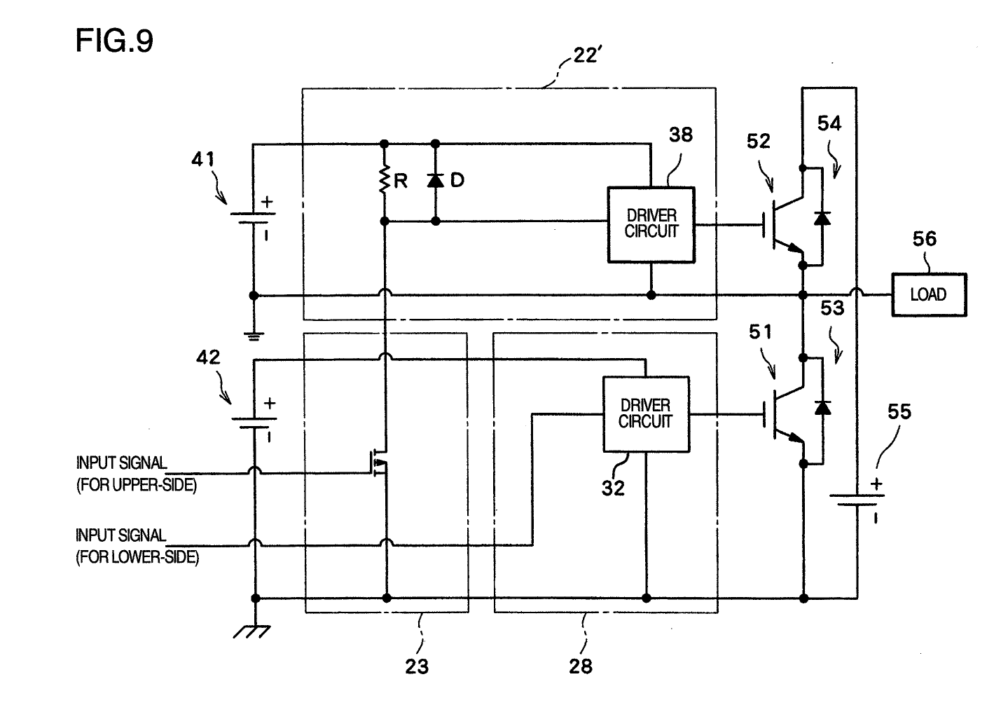

FIG. 9 shows a semiconductor circuit as a still further embodiment of this invention, which corresponds to the embodiment shown in FIG. 1. This semiconductor circuit comprises a lower-side drive circuit 28, an upper-side drive circuit 22′, a signal transfer circuit 23 including a SiC-nMOSFET 11, and power sources 41, 42. The outputs of the lower-side and upper-side drive circuits 28, 22′ are supplied to the gate terminals of the corresponding voltage-driven switching devices (IGBTs in this case) 51, 52. This circuit configuration described so far is the same as that shown in FIG. 1, but it differs from the embodiment shown in FIG. 1 in that the lower-side drive circuit 28 lacks the pulse generator 31.

In this semiconductor circuit, the input signal for the upper side is applied directly to the gate of the SiC-nMOSFET 11 of the signal transfer circuit 23. Namely, the SiC-nMOSFET 11 is not driven by a pulse signal but by the input signal directly. It will be needless to say that the SiC-nMOSFET 11 can be replaced by a SiC junction FET (JFET) or an n-gate IGBT in this case, too. If the SIC-JFET is used in place of the SiC-nMOSFET, the loss will further be reduced, which leads to the improvement in reliability.

The wide band-gap semiconductor devices described in the foregoing are SiC devices or GaN devices, but it is needless to say that the wide band-gap semiconductor devices used in the embodiments of this invention can be devices made of diamond.

As described hitherto, the embodiments of this invention are well suited for the cases where it is necessary to increase the pulse width of the set or reset pulse, and yet can meet the seemingly opposing issues by mitigating the requirement for decreasing the pulse width. Moreover, this invention will lead to the economy of the cost of the semiconductor circuit as a whole since the wide band-gap semiconductor devices are used only in the limited portion of the whole semiconductor circuit.

It should be further understood by those skilled in the art that although the foregoing description has been made on embodiments of the invention, the invention is not limited thereto and various changes and modifications may be made without departing from the spirit of the invention and the scope of the appended claims.

1. A semiconductor circuit for driving an inverter device with a load connected at the potential at the intermediate point between the high-voltage switching device and the low-voltage switching device, comprising
a pulse generator for generating pulse signals upon receiving the input signals supplied thereto at the time instants which correspond to the turn-on and turn-off of the high-voltage switching device in the inverter device,
a driver circuit for driving the high-voltage switching device, and
a signal transfer circuit for transferring the pulse signals generated by the pulse generator to the driver circuit,
wherein a wide band-gap semiconductor device is used in the signal transfer circuit to transfer the pulse signals.

2. A semiconductor circuit as claimed in claim 1, wherein the wide band-gap semiconductor device used in the signal transfer circuit may be selected from among a SiC device, a GaN device and a device made of diamond.

3. A semiconductor circuit as claimed in claim 1, wherein the wide band-gap semiconductor device used in the signal transfer circuit is selected from among a MOSFET, a junction FET and an IGBT.

4. A semiconductor circuit as claimed in claim 1, further comprising
a metal substrate,
silicon chips provided on the metal substrate and having the driver circuits formed thereon, and
a wide band-gap semiconductor device mounted on the metal substrate and connected with the driver circuits through wire bonding.

5. A semiconductor circuit as claimed in claim 4, wherein the silicon chips and the wide band-gap semiconductor device are attached to the metal substrate by soldering with high melting-point solder.

6. A semiconductor circuit as claimed in claim 4, wherein plural wide band-gap semiconductor devices are mounted on the metal substrate, with the bonding wires connecting the wide band-gap semiconductor devices with the driver circuits having substantially the same lengths.

7. A semiconductor circuit as claimed in claim 1, wherein a silicon chip is disposed on the metal substrate, and the wide band-gap semiconductor device is formed by disposing the driver circuits on the silicon chip and selectively forming a GaN layer on one portion of the surface of the silicon chip.
